(19) United States
(12) Patent Application Publication
(10) Pub. No.: US 2007/0148851 A1
(43) Pub. Date: Jun. 28, 2007

(54) METHOD OF PROGRAMMING EEPROM HAVING SINGLE GATE STRUCTURE

(76) Inventors: Myung-hee Kim, Suwon-si (KR); Geun-sook Park, Suwon-si (KR); Sang-bae Yi, Seoul (KR); Ho-ik Hwang, Seoul (KR); Hye-young Park, Seoul (KR)

Correspondence Address: Frank Chau, Esq.;F. CHAU & ASSOCIATES, LLC, 130 Woodbury Road, Woodbury, NY, 11797, US

(21) Appl. No.: 11/608,529

(22) Filed: Dec. 8, 2006

(30) Foreign Application Priority Data
Dec. 24, 2005 (KR) 10-2005-0129132

(51) Int. Cl. H01L 21/8238

(52) U.S. Cl. 438/201

(57) ABSTRACT

A method of programming an EEPROM including a first active region, a second active region and a third active region located separately in a semiconductor substrate, a common floating gate above and intersecting the active regions, first impurity regions located at both sides of the common floating gate in the first active region, second impurity regions located at both sides of the common floating gate in the second active regions and third impurity region, located at both sides of the common floating gate in the third active region. The method includes: applying a programming voltage to the first impurity regions in the first active region and the third impurity regions in the third active region; and applying a ground voltage to the second impurity regions in the second active region.

### CROSS-REFERENCE TO RELATED PATENT APPLICATION

This application claims priority to Korean Patent Application No. 10-2005-0129132, filed on Dec. 24, 2005 the disclosure of which is herein incorporated by reference in its entirety.

### BACKGROUND OF THE INVENTION

1. Technical Field

The present disclosure relates to an electrically erasable programmable read-only memory (EEPROM) and, more particularly, to a single poly EEPROM.

2. Discussion of Related Art

EEPROM is a type of non-volatile memory, which has the capability to store data after the power is turned off. An EEPROM can be integrated on an application-specific integrated circuit (ASIC), for example, a display drive chip.

EEPROM devices may employ double-gate type structures. However, the additional manufacturing process steps required to form double-gate structures add cost and time in manufacturing the devices. Single poly EEPROM technologies have been developed, in which an EEPROM can be designed in a chip using a general CMOS process without additional process stages.

The single poly EEPROM cell includes a gate structure which is similar to a laterally spread stacked double-gate structure. The higher the coupling ratio of the EEPROM, the faster the programming speed. The coupling ratio can be increased by enlarging the area of a gate electrode, but this increases the size of the EEPROM device. A need exists for a method of programming a single poly EEPROM to increase the programming speed by raising the coupling ratio without enlarging the area of a gate electrode of the EEPROM.

### SUMMARY OF THE INVENTION

According to an exemplary embodiment of the present invention, there is provided a method of programming an EEPROM including a first active region, a second active region and a third active region located separately in a semiconductor substrate, a common floating gate above and intersecting the active regions, first impurity regions located at both sides of the common floating gate in the first active region, second impurity regions located at both sides of the common floating gate in the second active region, and third impurity regions located at both sides of the common floating gate in the third active region. The method includes: applying a programming voltage to the first impurity regions in the first active region and the third impurity regions in the third active region; and applying a ground voltage to the second impurity regions in the second active region.

According to an exemplary embodiment of the present invention, there is provided a method of programming an EEPROM. The method includes: applying a programming voltage to the first impurity regions in the first active region and the second impurity regions in the second active region; and applying a ground voltage to the third impurity regions in the third active region.

According to an exemplary embodiment of the present invention, there is provided a method of programming an EEPROM. The method includes. applying a programming voltage to the first impurity regions in the first active region and the second impurity region; in the second active regions and applying a voltage of opposite polarity to the programming voltage to the third impurity regions in the third active region.

The area where the common floating gate overlaps the first active region may be larger than the area where the common floating gate overlaps the second active region and the area where the common floating gate overlaps the third active region.

According to an exemplary embodiment of the present invention, there is provided a method of programming an EEPROM including a fourth impurity region in the first active region, a fifth impurity region in the second active region and a sixth impurity region in the third active region. The method includes: applying the same voltage as applied to the first impurity region to the fourth impurity region; applying the same voltage as applied to the second impurity region to the fifth impurity region; and applying the same voltage as applied to the third impurity region to the sixth impurity region.

The programming voltage may be within the voltage range which allows electrons of the second active region to tunnel into the common floating gate by F-N tunneling.

The programming voltage may be in the range of approximately 15 V to approximately 20 V, and the voltage of opposite polarity to the programming voltage may be in the range of approximately −3 V to approximately −5 V,

The EEPROM may include: a first well located in the semiconductor substrate of the first active region; a second well located in the semiconductor of the second active region; a third well located in the semiconductor of the third active region; and a fourth well surrounding the first well and the second well in the semiconductor substrate.

According to an exemplary embodiment of the present invention, there is provided a method of programming an EEPROM including a first active region, a second active region and a third active region located separately in a P-type semiconductor substrate, a common floating gate above and intersecting the first, second and third active regions, P-type first impurity regions and an N-type impurity region located at both sides of the common floating gate in the first active region, P-type second impurity regions and an N-type fifth impurity region located at both sides of the common floating gate in the second active region, and N type third impurity regions and a P-type sixth impurity region located at both sides of the common floating gate in the third active region. The method includes: applying a programming voltage to the third impurity regions and the sixth impurity region in the third active region; and applying a ground voltage to the second impurity regions and the fifth impurity region of the second active region.

According to an exemplary embodiment of the present invention, there is provided a method of programming an EEPROM. The method includes: applying a programming voltage to the second impurity regions and the fifth impurity region in the second active region; and applying a ground voltage to the third impurity regions and the sixth impurity region of the third active region.

According to an exemplary embodiment of the present invention, there is provided a method of programming an EEPROM. The method includes: applying a programming voltage to the second impurity regions and the fifth impurity region in the second active region; and applying a voltage of opposite polarity to the programming voltage to the third impurity regions and the sixth impurity region of the third active region.

### BRIEF DESCRIPTION OF THE DRAWINGS

The present invention will become readily apparent to those of ordinary skill in the art when descriptions of exemplary embodiments thereof are read with reference to the accompanying drawings.

FIG. 1 is an equivalent circuit diagram of a single-gate structure of a unit cell of an EEPROM.

FIG. 2 is a layout view of a single-gate structure of a unit cell of an EEPROM.

FIG. 3 is a cross-sectional view taken along lines I-I, II-II and III-III of FIG. 2 from the left, illustrating voltages applied in a method of programming an EEPROM according to an exemplary embodiment of the present invention.

FIG. 4 is a cross-sectional view taken along lines I-I, II-II and III-III of FIG. 2 from the left, illustrating a method of programming an EEPROM according to an exemplary embodiment of the present invention.

FIG. 5 is a cross-sectional view taken along lines I-I, II-II and III-III of FIG. 2 from the left, illustrating a method of programming an EEPROM according to an exemplary embodiment of the present invention.

### DESCRIPTION OF EXEMPLARY EMBODIMENTS

Hereinafter, exemplary embodiments of the present invention will be described in detail with reference to the accompanying drawings. In the drawings, the thicknesses and relative sizes of layers and regions may be exaggerated for clarity. Like reference numerals refer to similar or identical elements throughout the description of the figures.

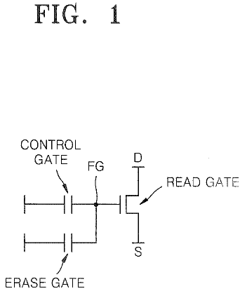

FIG. 1 is an equivalent circuit diagram of a single-gate structure of a unit cell of an EEPROM to which a method of programming according to an exemplary embodiment of the present invention is applied. Referring to FIG. 1, the unit cell of the EEPROM having the single gate structure includes a read gate READ GATE, a control gate CONTROL GATE, and an erase gate ERASE GATE having a common a floating gate (FG). The read gate is a transistor element, and the control gate and the erase gate are capacitive elements.

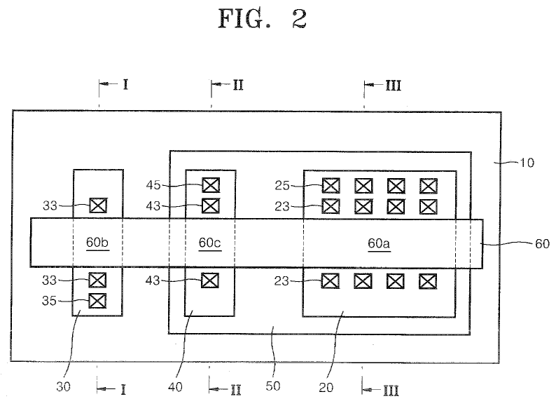

FIG. 2 is a layout view of a single-gate structure of a unit cell of an EEPROM to which a programming method according to an exemplary embodiment of the present invention is applied. Referring to FIG. 2, a semiconductor substrate 10 includes a control active region 20, an erase active region 30, and a read active region 40, which are separated from one another. The active regions may be arranged in the following order: the erase active region 30, the read active region 40 and the control active region 20. It is to be understood that the active regions may be configured in various arrangements.

A common floating gate 60 is positioned to intersect the first, second and third active regions 20, 30, and 40. The floating gate 60 may be an N-type gate, such as for example, a poly-silicon layer doped by N type impurity.

The floating gate 60 includes a control gate portion 60a overlapping the control active region 20, a read gate portion 60c overlapping the read active region 40, and an erase gate portion 60b overlapping the erase active region 30. The area where the floating gate 60 overlaps the control active region 20 may be larger than the area where the floating gate 60 overlaps the erase active region 30 and the area where the floating gate 60 overlaps the read active region 40, and this can aid capacitive coupling between the control active region 20 and the floating gate 60.

An N-type control well (not shown) is located in a portion of the semiconductor substrate corresponding to the control active region 20. A pair of P-type control impurity regions 23 is formed in the control active region 20 at both sides of the control gate portion 60a. An N-type control well contact region 25 is formed in the control active region 20, spaced apart from the control gate portion 60a and adjacent to one of the P-type control impurity regions 23. The control well contact region 25 may the same P-type as the control well 20, where the concentration of impurities may be high.

An N-type erase well is located in a portion of the semiconductor substrate corresponding to the erase active region 30. A pair of P-type erase impurity regions 33 is formed in the erase active region 30 at both sides of the erase gate portion 60b. An N-type erase well contact region 35 is formed in the erase active region 30, spaced apart from the erase gate portion 60b and adjacent to one of the P-type erase impurity regions 33. The erase well contact region 35 may be the same P-type as the erase well 5, where the concentration of impurity may be high.

A P-type read well 40 is located in a portion of the semiconductor substrate corresponding to the read active region 40. N type source/drain regions 43 are formed in the read active region 40 at both sides of the read gate portion 60c. A P-type read well contact region 45 is formed in the read active region 40, spaced apart from the read gate portion 60c and adjacent to one of the source/drain regions 43. The read well contact region 45 may be the same P-type as the read well 40, where the concentration of impurity is high. An N-type deep well 50 is formed in the semiconductor substrate, surrounding the control well 20 and the read well 40.

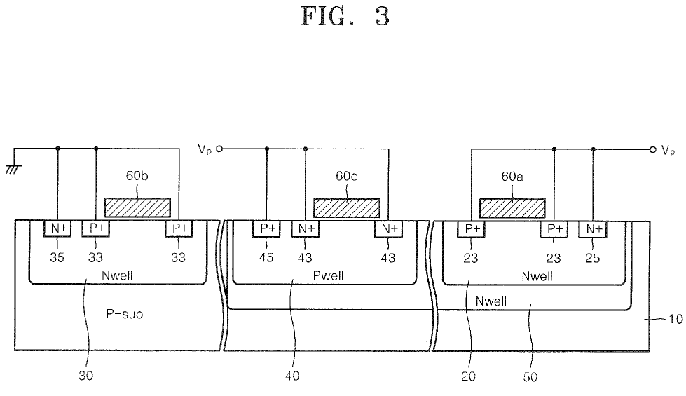

FIG. 3 is a cross-sectional view taken along lines I-I, II-II and III-III of FIG. 2 from the left, and illustrates voltages applied in a method of programming an EEPROM according to an exemplary embodiment of the present invention.

Referring to FIG. 3, a programming voltage V_{P} is applied to the control impurity regions 23, the control well contact region 25 of the control active region 20, the read impurity regions 43 and the read well contact region 45 of the read active region 40. A ground voltage us applied to the erase impurity regions 33 and the erase well contact region 35 of the erase active region 30. The applied programming voltage V_{P} can be capacitively coupled to the floating gate 60 by a capacitive circuit including the control active region 20, the control impurity regions 23, and the control gate portion 60 a, and a capacitive circuit including the read active region 40, the read impurity regions 43, and the read gate portion 60 c. A strong electric field may be formed between the erase gate portion 60b and the grounded erase active region 30 as the programming voltage V_{P} is capacitively coupled to the floating gate 60. Electrons of the erase well 30 can tunnel into the erase gate portion 60b by Fowler-Nordheim (F-N) tunneling and are stored in the floating gate 60 by the strong electric field. At this time, the programming voltage V_{P} is within the voltage range which allows the electrons of the erase active region 30 to tunnel into the erase gate portion 60b by F-N tunneling. For example, the programming voltage V_{P} may be approximately 15 V.

According to a method of programming an EEPROM of the exemplary embodiment of the present invention described in connection with FIG. 3, the programming voltage is applied to the read well contact region 45, the read impurity regions 43, the control well contact region 25 and the control impurity regions 23 and, the capacitive coupling ratio to the floating gate 60 is greater than that when the programming voltage is applied only to the control well contact region 25 and the control impurity regions 23. Although substantially the same voltage is applied, the capacitive coupling ratio is greater, which increases a tunneling current and the programming speed.

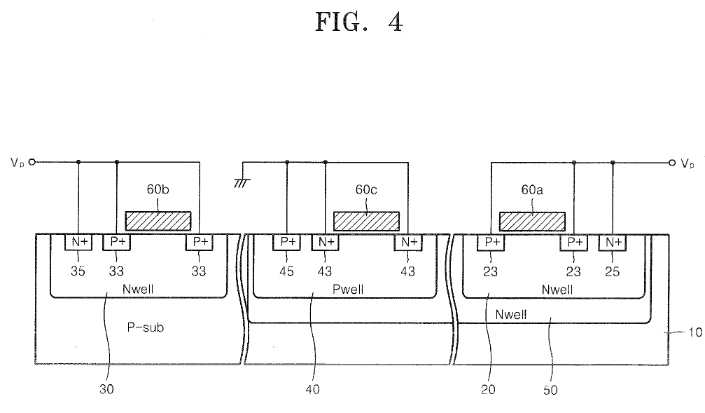

FIG. 4 is a cross-sectional view taken along lines I-I, II-II and III-III of FIG. 2 from the left, and illustrates voltages applied in a method of programming an EEPROM according to an exemplary embodiment of the present invention.

Referring to FIG. 4, a programming voltage V_{P} is applied to the control impurity regions 23, the control well contact region 25 of the control active region 20, the erase impurity regions 33 and the erase well contact region 35 of the erase active region 30. A ground voltage is applied to the read impurity regions 43 and the read well contact region 45 of the read active region 40. The applied programming voltage V_{P} can be capacitively coupled to the floating gate 60 by a capacitive circuit including the control active region 20, the control impurity regions 23, and the control gate portion 60a, and a capacitive circuit including the erase active region 30, the erase impurity regions 33, and the erase gate portion 60b. A strong electric field may be formed between the read gate portion 60c and the grounded read active region 40 as the programming voltage V_{P} is capacitively coupled to the floating gate 60. Electrons of the read well 40 can tunnel into the read gate portion 60c by Fowler-Nordheim (F-N) tunneling and are stored in the floating gate 60 by the strong electric field. The programming voltage V_{P} is within the voltage range which allows the electrons of the read active region 40 to tunnel into the read gate portion 60c by F-N tunneling. For example, the programming voltage V_{P} may be approximately 15 V

According to a method of programming an EEPROM of the exemplary embodiment of the present invention described in connection with FIG. 4, the programming voltage is applied to the erase well contact region 35, the erase impurity regions 33, the control well contact region 25 and the control impurity regions 23, and the capacitive coupling ratio to the floating gate 60 is greater than that when the programming voltage is applied only to the control well contact region 25 and the control impurity regions 23. Although the same voltage is applied, the capacitive coupling ratio is greater, which increases a tunneling current and the programming speed.

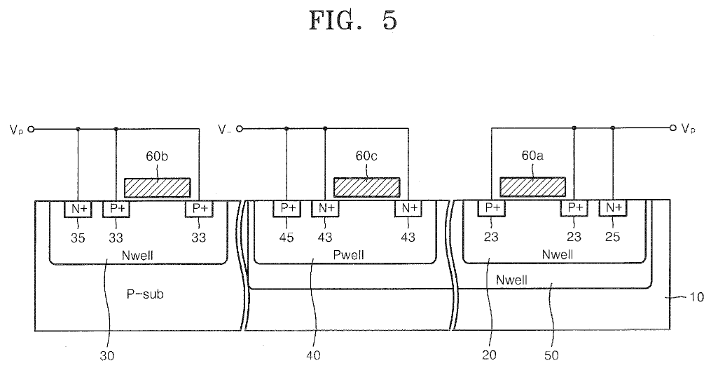

FIG. 5 is a cross-sectional view taken along lines I-I, II-II and Ill-III of FIG. 2 from the left, and illustrates a voltage applied in a method of programming an EEPROM according to an exemplary embodiment of the present invention.

Referring to FIG. 5, a programming voltage V_{P} is applied to the control impurity regions 23, the control well contact region 25 of the control active region 20, the erase impurity regions 33 and the erase well contact region 35 of the erase active region 30. A negative voltage ‘V−’ is applied to the read impurity regions 43 and the read well contact region 45 of the read active region 40. The applied programming voltage V_{P} can be capacitively coupled to the floating gate 60 by a capacitive circuit including the control active region 20, the control impurity regions 23, and the control gate portion 60a, and a capacitive circuit including the erase active region 30, the erase impurity regions 33, and the erase gate portion 60b. A strong electric field may be formed between the read gate portion 60c and the read active region 40 to which the negative voltage is applied as the programming voltage V_{P} is capacitively coupled to the floating gate 60. Since the negative voltage ‘V−’ is applied to the read impurity region 43 and the read well contact region 45 of the read active region 40, a stronger electric field may be formed between the read gate portion 60c and the read active region 40 than that when a ground voltage is applied. Electrons of the read well 40 can tunnel into the read gate portion 60c by Fowler-Nordheim (F-N) tunneling and are stored in the floating gate 60 by the strong electric field. The programming voltage V_{P} is within the voltage range which allows the electrons of the read active region 40 to tunnel into the read gate portion 60c by F-N tunneling. For example, the programming voltage V_{P} may be approximately 15 V.

According to a method of programming an EEPROM of the exemplary embodiment of the present invention described in connection with FIG. 4, when the programming voltage ‘V_{P}’ is applied, a capacitive coupling with the floating gate 60 occurs in the erase active region 30 as well as the control active region 20, increasing the coupling ratio. A stronger electric field may be formed between the floating gate 60 and the read active region 40 capacitively coupled by applying the negative voltage ‘V−’ to the read active region 40, and the F-N tunneling may be improved, and the programming speed may be increased.

According to an exemplary embodiment of the present invention, when programming the EEPROM having the single gate structure, the programming voltage is applied to the control active region and the programming voltage is applied to either the erase active region or the read active region, increasing the capacitive coupling ratio to the floating gate, and the programming speed may be increased.

According to an exemplary embodiment of the present invention, a programming voltage is applied to the control active region and the erase active region and a ground voltage is applied to the read active region. According to an exemplary embodiment of the present invention, a programming voltage is applied the control active region and the read active region and the ground voltage is applied to the erase active region, increasing a capacitive coupling ratio to the floating gate.

According to an exemplary embodiment of the present invention, the programming voltage is applied to the control active region and the read active region and applied to the erase active region, to increase the electric field between the floating gate and the erase active region capacitively coupled, and F-N tunneling may be improved.

According to an exemplary embodiment of the present invention, a negative voltage is applied to the control active region and the erase active region to generate a stronger electric field between the read active region and the floating gate capacitively coupled, and F-N tunneling-N tunneling may be improved, and the programming speed may be increased.

According to an exemplary embodiment of the present invention, a method of programming a single poly EEPROM increases the speed of a program by raising the coupling ratio without enlarging the area of a gate electrode of the single poly EEPROM.

Although the exemplary embodiments of embodiments of the present invention have been described in detail with reference to the accompanying drawings for the purpose of illustration, it is to be understood that the inventive processes and apparatus should not be construed as limited thereby. It will be readily apparent to those of ordinary skill in the art that various modifications to the foregoing exemplary embodiments may be made without departing from the scope of the invention as defined by the appended claims, with equivalents of the claims to be included therein.

What is claimed is:

1. A method of programming an EEPROM including a first active region, a second active region and a third active region located separately in a semiconductor substrate, a common floating gate above and intersecting the first, second and third active regions, first impurity regions located at both sides of the common floating gate in the first active region, second impurity regions located at both sides of the common floating gate in the second active region, and third impurity regions located at both sides of the common floating gate in the third active region, the method comprising:
applying a programming voltage to the first impurity regions in the first active region and the third impurity regions in the third active region; and
applying a ground voltage to the second impurity regions in the second active region.

2. The method of claim 1, wherein an area where the common floating gate overlaps the first active region is larger than an area where the common floating gate overlaps the second active region and an area where the common floating gate overlaps the third active region.

3. The method of claim 1, wherein the EEPROM further includes a fourth impurity region in the first active region, a fifth impurity region in the second active region and a sixth impurity region in the third active region, and the method further comprises:
applying the same voltage as applied to the first impurity region to the fourth impurity region;
applying the same voltage as applied to the second impurity region to the fifth impurity region; and
applying the same voltage as applied to the third impurity region to the sixth impurity region.

4. The method of claim 3, wherein the EEPROM further comprises:
a first well located in the semiconductor substrate of the first active region;
a second well located in the semiconductor substrate of the second active region; and
a third well located in the semiconductor substrate of the third active region.

5. The method of 4, wherein the EEPROM further comprises a fourth well surrounding the first well and the second well in the semiconductor substrate.

6. The method of claim 1, wherein the programming voltage is within the voltage range which allows electrons of the second active region to tunnel into the common floating gate by F-N tunneling.

7. The method of claim 1, wherein the programming voltage is in the range of approximately 15 V to approximately 20 V.

8. A method of programming an EEPROM including a first active region, a second active region and a third active region located separately in a semiconductor substrate, a common floating gate above and intersecting the first, second and third active regions, first impurity regions located at both sides of the common floating gate in the first active region, second impurity regions located at both sides of the common floating gate in the second active region, and third impurity regions located at both sides of the common floating gate in the third active region, the method comprising:
applying a programming voltage to the first impurity regions in the first active region and the second impurity regions in the second active region; and
applying a ground voltage to the third impurity regions in the third active region.

9. The method of claim 8, wherein the programming voltage is within the voltage range which allows electrons of the third active region to tunnel into the common floating gate by F-N tunneling.

10. A method of programming of an EEPROM including a first active region, a second active region and a third active region located separately in a semiconductor substrate, a common floating gate above and intersecting the first, second and third active regions first impurity regions located at both sides of the common floating gate in the first active region, second impurity regions located at both sides of the common floating gate in the second active region, and third impurity regions located at both sides of the common floating gate in the third active region, the method comprising:
applying a programming voltage to the first impurity regions in the first active region and the second impurity regions in the second active region; and
applying a voltage of opposite polarity to the programming voltage to the third impurity regions in the third active region.

11. The method of claim 10, wherein the voltage of opposite polarity to the programming voltage is in the range of approximately −3 V to approximately −5 V.

12. A method of programming an EEPROM including a first active region, a second active region and a third active region located separately in a P-type semiconductor substrate, a common floating gate above and intersecting the first, second and third active regions, P-type first impurity regions and an N type impurity region located at both sides of the common floating gate in the first active region, P-type second impurity regions and an N-type fifth impurity region located at both sides of the common floating gate in the second active region, and N-type third impurity regions and a P-type sixth impurity region located at both sides of the common floating gate in the third active region, the method comprising:
applying a programming voltage to the third impurity regions and the sixth impurity region in the third active region; and
applying a ground voltage to the second impurity regions and the fifth impurity region of the second active region.

13. The method of claim 12, wherein the programming voltage is within the voltage range which allows electrons of the second active region to tunnel into the common floating gate by F-N tunneling.

14. The method of claim 13, wherein the EEPROM further comprises:
an N-type first welt located in the semiconductor substrate of the first active region;
an N-type second well located in the semiconductor of the second active region; and
a P-type third well located in the semiconductor of the third active region.

15. The method of claim 14, wherein the EEPROM further comprises an N-type deep fourth well surrounding the first well and the second well in the semiconductor substrate.

16. A method of programming an EEPROM including a first active region, a second region and a third active region located separately in a P-type semiconductor substrate, a common floating gate above and intersecting the first, second and third active regions, P-type first impurity regions and an N-type impurity region located at both sides of the common floating gate in the first active region, P-type second impurity regions and an N-type fifth impurity region located at both sides of the common floating gate in the second active region, and N-type third impurity regions and a P-type sixth impurity region located at both sides of the common floating gate in the third active region, the method comprising
applying a programming voltage to the second impurity regions and the fifth impurity region in the second active region.

17. The method of claim 16, further comprising applying a ground voltage to the third impurity regions and the sixth impurity region of the third active region.

18. The method of claim 16, further comprising
applying a voltage of opposite polarity to the programming voltage to the third impurity regions and the sixth impurity region of the third active region.

19. The method of claim 18, wherein the programming voltage is within the voltage range which allows electrons of the third active region to tunnel into the common floating gate by F-N tunneling.

20. The method of claim 18, wherein the programming voltage is in the range of approximately 15 V to approximately 20 V.

21. The method of claim 1S, wherein the voltage of opposite polarity to the programming voltage is in the range of approximately −3 V to approximately −5 V.

22. The method claim 18, wherein an area where the common floating gate overlaps the first active region is larger than an area where the common floating gate overlaps the second active region and an area where the common floating gate overlaps the third active region.
